(19) United States
(12) Patent Application Publication
(10) Pub. No.: US 2024/0224722 A1
(43) Pub. Date: Jul. 4, 2024

(54) COVER MODULE AND DISPLAY DEVICE INCLUDING THE SAME

(71) Applicant: LG Display Co., Ltd., Seoul (KR)

(72) Inventors: HyeongMin Jeon, Paju-si (KR); Youngjoo Park, Paju-si (KR)

(73) Assignee: LG Display Co., Ltd., Seoul (KR)

(21) Appl. No.: 18/371,738

(22) Filed: Sep. 22, 2023

(30) Foreign Application Priority Data
Dec. 30, 2022 (KR) 10-2022-0191178

(51) Int. Cl. H10K 59/80; H10K 59/12

(52) U.S. Cl. CPC H10K 59/873; H10K 59/1201; H10K 2102/311

(57) ABSTRACT

Aspects of the disclosure relate to a cover module and a display device including the same. Specifically, a display device comprises a display panel and a cover module disposed on the display panel. The cover module includes an adhesive layer disposed on the display panel and a coating layer. The coating layer is disposed on an outermost part of the display device and a surface hardness of the display device is identical to a hardness of the coating layer. Thus, a cover module having excellent flexibility and high surface hardness and a display device including the cover module is disclosed.

### CROSS-REFERENCE TO RELATED APPLICATIONS

This application claims priority from Korean Patent Application No. 10-2022-0191178, filed on Dec. 30, 2022, which is hereby incorporated by reference for all purposes as if fully set forth herein.

### BACKGROUND

### Field

Embodiments of the disclosure relate to a cover module and a display device including the cover module.

### Description of Related Art

As films replace glass or high-hardness substrates for display devices, foldable, flexible display devices are being developed. Such a display device may be manufactured in various shapes that may be thin, light, impact-resistant, foldable, or rollable.

Various optical elements of such a display device must have good flexibility and have a low inverse curvature radius considering usability. Further, since the cover module covering the display panel is positioned at the outermost part of the display device, it should have high hardness and not be impressed when pressed by hand.

### SUMMARY

Aspects of the disclosure relate to a cover module having excellent flexibility and high surface hardness by not including a base layer, and a display device including the same.

Aspects of the disclosure relate to a cover module having high reliability even when bent, folded, slid, and rolled by including a coating layer containing a release agent, and a display device including the same.

Aspects of the disclosure relate to a cover module capable of implementing a uni-material product in which material components are simplified and unified by including a coating layer disposed on a display panel, and a display device including the same.

Aspects of the disclosure may provide a display device comprising a display panel and a cover module disposed on the display panel, wherein the cover module includes an adhesive layer disposed on the display panel and a coating layer disposed on the adhesive layer, wherein the coating layer is disposed on an outermost part of the display device, and wherein a surface hardness of the display device is identical to a hardness of the coating layer.

Aspects of the disclosure may provide a cover module comprising an adhesive layer and a coating layer disposed on the adhesive layer, wherein the coating layer is disposed on an outermost part of the cover module, and wherein a surface hardness of the cover module is identical to a surface hardness of the coating layer.

According to Aspects of the disclosure, there may be provided a cover module having excellent flexibility and high surface hardness by not including a base layer, and a display device including the same.

According to Aspects of the disclosure, there may be provided a cover module having high reliability even when bent, folded, slid, and rolled by including a coating layer containing a release agent, and a display device including the same.

According to Aspects of the disclosure, there may be provided a cover module capable of implementing a uni-material product in which material components are simplified and unified by including a coating layer disposed on a display panel, and a display device including the same.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1A is a view schematically illustrating a structure of a display device according to aspects of the disclosure:

FIG. 1B is a view illustrating a structure of a cover module according to aspects of the disclosure:

FIG. 2 is a view illustrating a cross-sectional structure of a display device according to aspects of the disclosure:

FIGS. 3, 4, 5, and 6 are views illustrating a structure of a cover module according to aspects of the disclosure:

FIG. 7 is a view comparing the characteristics of cover modules according to an aspect of the disclosure:

FIG. 8 is a view schematically illustrating a process of forming a coating layer of a cover module according to aspects of the disclosure; and

FIG. 9 is a view schematically illustrating a process of bonding a coating layer to a rigidity reinforcement layer according to aspects of the disclosure.

### DETAILED DESCRIPTION

In the following description of examples or aspects of the disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the disclosure, detailed descriptions of well-known functions and components incorporated herein will be omitted when it is determined that the description may make the subject matter in some of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps” etc. a second element, it should be interpreted that, not only may the first element “be directly connected or coupled to” or “directly contact or overlap” the second element, but a third element may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before.” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the disclosure are described in detail with reference to the accompanying drawings.

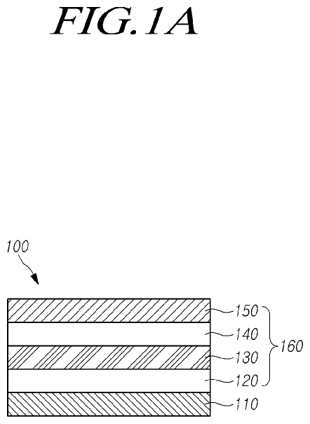

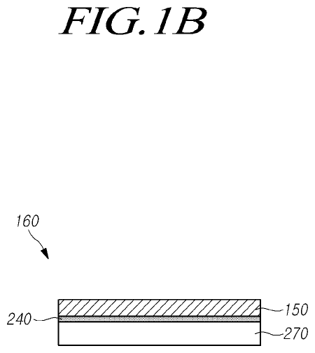

FIG. 1A is a view schematically illustrating a structure of a display device according to aspects of the disclosure.

Referring to FIG. 1A, a display device 100 according to aspects may include a display panel 110 and a cover module 160 disposed on the display panel 110.

The cover module 160 may include a first adhesive layer 120, a polarizing plate 130 disposed on the first adhesive layer 120, a second adhesive layer 140 disposed on the polarizing plate 130, and a coating layer 150 disposed on the second adhesive layer 140.

The display panel 110 according to aspects of the disclosure may be various display panels, such as an organic light emitting display panel, a touchscreen panel, or a liquid crystal display panel. However, in the following description, for convenience of description, the display panel 110 is an organic light emitting display panel.

The first adhesive layer 120 may adhere the polarizing plate 130 onto the display panel 110, and the second adhesive layer 140 may adhere the coating layer 150 onto the polarizing plate 130.

However, the structure of the display device 100 according to aspects of the disclosure is not limited thereto, and if the coating layer 150 itself has adhesivity, the second adhesive layer 140 may be omitted.

The polarizing plate 130 may be used to enhance the optical characteristics of the display device 100. For example, the polarizing plate 130 may prevent reflection of external light or implement polarization.

Although not shown in FIG. 1A, the polarizing plate 130 may be formed of a single layer or multiple layers.

When the polarizing plate 130 is formed of multiple layers, the polarizing plate 130 may include a polarizer and a protection layer formed on one or both surfaces of the polarizer, but the multilayer structure of the polarizing plate 130 according to aspects of the disclosure is not limited thereto, but may be any structure composed of two or more layers.

However, the structure of the display device 100 according to aspects of the disclosure is not limited thereto and may include a structure in which the polarizing plate 130 is not disposed on the display panel 110. In this case, at least one of the first adhesive layer 120 and the second adhesive layer 140 may be omitted.

As shown in FIG. 1A, in the display device 100 according to aspects of the disclosure, the coating layer 150 may be disposed on the outermost part.

In some aspects, the coating layer 150 may prevent the display panel 110 from being damaged due to an external force applied to the display device 100.

The coating layer 150 may be disposed on the display surface of the display panel 110.

Referring to FIG. 1A, the coating layer 150 according to aspects of the disclosure may be attached on the display panel 110 through the adhesive layers 120 and 140 without a separate base layer.

In a conventional display device with a base layer, bending or folding the display device 100 may be limited due to the nature of the base layer (e.g., transparent polyimide film, polyester film, acrylic film, urethane film, etc.). However, since the display device 100 according to aspects of the disclosure does not include a separate base layer, the display device 100 may be easy to bend or fold the display device 100.

The coating layer 150 according to aspects of the disclosure may be formed from a material having high flexibility and high hardness characteristics. Since the coating layer 150 is not damaged even in extreme curvature, the coating layer 150 may be applied to a foldable or rollable display device.

In some examples, the coating layer 150 according to aspects of the disclosure may have a pencil hardness of 8H to 9H, which is equivalent to a pencil hardness of glass. In other words, the coating layer 150 may have high hardness.

However, when a general cover window formed of glass is used to protect the display panel 110, the cover window has a high risk of breakage. To prevent the cover window from breaking, a shatterproof film is applied to the cover window that has a lower hardness than a glass cover window.

In one aspect, the general cover window may have a structure including a base layer disposed on the display panel to protect the display panel.

When the shatterproof film is disposed on the cover window; the cover window has a lower hardness as compared to when the cover window is disposed on the outermost part of the display device. In this case, the display device does not implement the surface hardness of a glass cover window and the surface hardness of the display device including a glass cover window may be substantially equal to the hardness of the shatterproof film.

In other words, the display device including a shatterproof film disposed on the cover window may be vulnerable to deformation and breakage due to low surface hardness.

In some aspects, because the coating layer 150 according to aspects of the disclosure has a surface hardness similar to that of glass, the probability of breakage may be reduced when an external force or stimulus is applied to the display device 100.

In some aspects, the coating layer 150 may have a thickness of 50 μm to 300 μm.

When the thickness of the coating layer 150 is smaller than 50 μm, the handleability is low; and when the thickness of the coating layer 150 is larger than 300 μm, the coating layer 150 may be difficult to manufacture and the flexibility may be reduced. Accordingly, the flexibility of the coating layer 150 is reduced.

In some aspects, the modulus of the coating layer 150 may be 200Mpa to 2000Mpa.

When the modulus of the coating layer 150 is smaller than 200Mpa, the softness of the coating layer 150 also increases, and the surface hardness of the display device 100 including the coating layer 150 may decrease. Further, when the modulus of the coating layer 150 is larger than 2000Mpa, the probability that the coating layer 150 may be broken may increase.

In some aspects, when the display device 100 including the coating layer 150 is folded, the folding radius, or bending radius, may be 1.5R to 7.0R. In some aspects, the folding radius or bending radius is based on a size or a thickness of the material expressed by R, as further described below.

For example, when the folding radius of the display device 100 is 1.5R to 3.0R, the thickness of the coating layer 150 may be 50 μm to 150 μm, and the modulus of the coating layer 150 may be 200Mpa to 1000Mpa and, when the folding radius of the display device 100 is 3.0R to 7.0R, the thickness of the coating layer 150 may be 150 μm to 300 μm, and the modulus of the coating layer 150 may be 1000Mpa to 2000Mpa.

As such, the thickness and modulus of the coating layer 150 are based on the folding radius of the display device 100. In some aspects of the disclosure, the coating layer 150 of the display device 100 may have a thickness of 50 μm to 150 μm and a modulus of 200Mpa to 1000Mpa when the folding radius of the display device 100 is 1.5R to 3.0R, and may have a thickness of 150 μm to 300 μm and a modulus of 1000Mpa to 2000Mpa when the folding radius of the display device 100 is 3.0R to 7.0R. Thus, the coating layer 150 may prevent degradation of the surface rigidity due to a reduction in the thickness or modulus of the coating layer 150 or deterioration of the foldability of the display device 100 due to a large thickness or modulus depending on the folding radius.

The coating layer 150 may include a base resin. The base resin of the coating layer 150 may include a siloxane resin. For example, the base resin may include at least one of acrylate siloxane or epoxy siloxane, but aspects of the disclosure are not limited thereto.

In some aspects, the coating layer 150 may be formed based on adding an elastomer to the backbone of the base resin. Non-limiting examples of an elastomer include at least one of a thermoplastic elastomer, a thermosetting elastomer, or a silicone elastomer.

As such, the coating layer 150 includes high flexibility and high surface hardness and may be formed through a material in which an elastomer is added to a base resin, such as a siloxane resin as described above.

The first adhesive layer 120 and the second adhesive layer 140 may be formed of a transparent material. For example, the first adhesive layer 120 and the second adhesive layer 140 may be optical clear adhesive (OCA), but aspects of the disclosure are not limited thereto.

The moduli of the first adhesive layer 120 and the second adhesive layer 140 may be 0.01 Mpa to 1Mpa.

When the moduli of the first adhesive layer 120 and the second adhesive layer 140 range from 0.01Mpa to 1 Mpa, it is possible to enhance impact resistance and minimize damage when bending or folding the display device 100.

The moduli of the first adhesive layer 120 and the second adhesive layer 140 may be the same. However, the configuration of the display device according to aspects of the disclosure is not limited thereto, and the moduli of the first adhesive layer 120 and the second adhesive layer 140 may be different.

In one aspect, the thicknesses of the first adhesive layer 120 and the second adhesive layer 140 may be 5 μm to 50 μm.

When the thicknesses of the first adhesive layer 120 and the second adhesive layer 140 are less than 5 μm, manufacturing may be difficult and uniformity of thickness may be low. When the thicknesses of the first adhesive layer 120 and the second adhesive layer 140 exceed 50 μm, flexibility and transparency may decrease.

The modulus of the polarizing plate 130 may be 2.5 Gpa to 3.5 Gpa, e.g., 3 Gpa. Since the modulus of the polarizing plate 130 is 2.5 Gpa to 3.5 Gpa, it is possible to manufacture the polarizing plate 130 having flexibility and impact resistance while effectively lowering external light reflection.

The structure of the cover module 160 according to aspects of the disclosure is not limited thereto.

FIG. 1B is a view illustrating a structure of a cover module according to aspects of the disclosure.

Referring to FIG. 1B, in some aspects of the disclosure, a cover module 160 may be included in a display device, and the cover module may include a rigidity reinforcement layer 270, an adhesive layer 240 disposed on the rigidity reinforcement layer 270, and a coating layer 150 disposed on the adhesive layer 240.

The rigidity reinforcement layer 270 may secure the rigidity of the surface of the display device.

The rigidity reinforcement layer 270 according to aspects of the disclosure may be formed of glass, a chemically tempered glass, and so forth.

The folding radius of the display device 100 including the cover module 160, which further includes the rigidity reinforcement layer 270, may be 3.0R to 7.0R. In some aspects, the thickness of the rigidity reinforcement layer 270 may be 50 μm to 120 μm. In one example, the rigidity reinforcement layer 270 may have a thickness of 70 μm to 90 μm. Further, the depth of chemical reinforcement, which may also be referred to as the depth of the compressive stress layer (DOL), of the rigidity reinforcement layer 270 may be 10 μm to 21 μm. In one example, the chemical reinforcement depth of the rigidity reinforcement layer 270 may be from 12 μm to 16 μm. Thus, it is possible to secure rigidity of the rigidity reinforcement layer 270 that is capable of damage-free folding.

The thickness of the adhesive layer 240 may be smaller than the thickness of the rigidity reinforcement layer 270 and the thickness of the coating layer 150.

For example, the adhesive layer 240 may have a thickness of 5 μm to 15 μm. When the thickness of the adhesive layer 240 is less than 5 μm, the application of a rolling process may be difficult because the thickness of the adhesive layer 240 is formed too thin. When the thickness of the adhesive layer 240 exceeds 15 μm, the effect of the adhesive layer 240 having a lower rigidity than that of the rigidity reinforcement layer 270 is greater and decreases the surface rigidity of the display device. In other words, when the thickness of the adhesive layer 240 exceeds 15 μm, surface rigidity may be lowered due to the adhesive layer 240 even when the display device includes the rigidity reinforcement layer 270 for increasing surface rigidity.

The structure in which the cover module 160 is applied to the display panel 110 is described below.

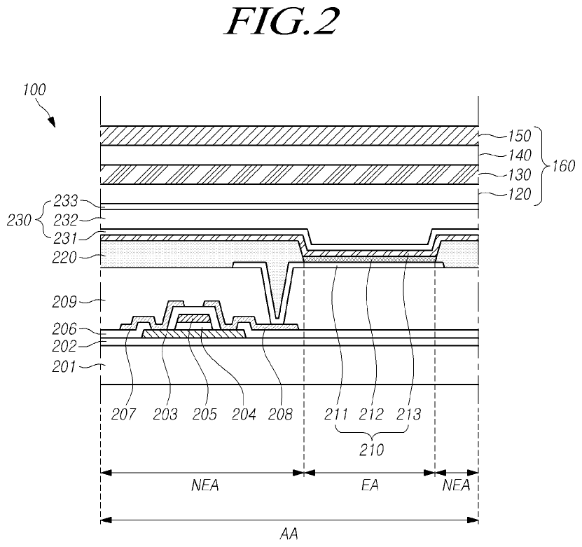

FIG. 2 is a view illustrating a cross-sectional structure of a display device according to aspects of the disclosure.

Referring to FIG. 2, the display panel 110 of the display device according to aspects of the disclosure may include an active area AA where an image is displayed and a non-active area other than the active area AA.

The display panel 110 may include at least one thin film transistor disposed on a substrate 201 in the active area AA and an organic light emitting element 210 disposed on the thin film transistor.

The thin film transistor may include an active layer 203, a gate electrode 205, a source electrode 207, and a drain electrode 208.

The organic light emitting element 210 may include a first electrode 211, a light emitting layer 212, and a second electrode 213.

In one aspect, a buffer layer 202 may be disposed on the substrate 201.

The buffer layer 202 may include an inorganic insulating material, such as silicon oxide (SiOx), silicon nitride (SiNx), or silicon oxynitride (SiON), but the disclosure is not limited thereto.

As shown in FIG. 2, the buffer layer 202 has a single-layer structure, but the buffer layer 202 of the disclosure may have a multi-layer structure.

If the buffer layer 202 has a multi-layer structure, the buffer layer 202 may include at least two inorganic insulating materials among inorganic materials, such as silicon oxide (SiOx), silicon nitride (SiNx), or silicon oxynitride (SiON), and layers may be alternately disposed, but the disclosure is not limited thereto.

In the following description, for convenience, a buffer layer 202 having a single layer is described.

An active layer 203 of the thin film transistor may be disposed on the buffer layer 202.

The active layer 203 may be various types of semiconductor layers. For example, the active layer 203 may be one selected from among an oxide semiconductor, an amorphous silicon semiconductor, and a polysilicon semiconductor, but the disclosure is not limited thereto.

A gate insulation film 204 may be disposed on the active layer 203.

The gate insulation film 204 may include an inorganic insulating material, such as silicon oxide (SiOx), silicon nitride (SiNx), or silicon oxynitride (SiON), but the disclosure is not limited thereto.

Although FIG. 2 illustrates a structure in which the gate insulation film 204 is disposed on a portion of the upper surface of the active layer 203, the disclosure is not limited thereto, and the gate insulation film 204 is disposed covering the active layer 203.

A gate electrode 205 of the thin film transistor may be disposed on the gate insulation film 204.

The gate electrode 205 may include may comprise a metallic material or compound such as aluminum (Al), gold (Au), silver (Ag), copper (Cu), tungsten (W), molybdenum (Mo), chromium (Cr), tantalum (Ta), and titanium (Ti), or alloys thereof, but the disclosure is not limited thereto.

An inter-layer insulation layer 206 may be disposed on the gate electrode 205.

The inter-layer insulation layer 206 may include an inorganic insulating material, such as silicon oxide (SiOx), silicon nitride (SiNx), or silicon oxynitride (SiON), but the disclosure is not limited thereto.

A source electrode 207 and a drain electrode 208 of the thin film transistor may be disposed on the inter-layer insulation layer 206 and may be spaced apart from each other.

In aspects of the disclosure, the source electrode 207 may be the drain node of the semiconductor device, and drain electrode 208 may be the source node of the semiconductor device.

The source electrode 207 and the drain electrode 208 may include any one of metals, such as aluminum (Al), gold (Au), silver (Ag), copper (Cu), tungsten (W), molybdenum (Mo), chromium (Cr), tantalum (Ta), and titanium (Ti), or alloys thereof, but the disclosure is not limited thereto.

Each of the source electrode 207 and the drain electrode 208 may be connected with a portion of the upper surface of the active layer 203 through a contact hole provided in the inter-layer insulation layer 206.

A planarization layer 209 may be disposed on the substrate 201 on which the source electrode 207 and the drain electrode 208 are disposed.

In some cases, a protective film (not shown) including an inorganic insulating material may be further disposed under the planarization layer 209.

A first electrode 211 of the organic light emitting element 210 may be disposed on a portion of the upper surface of the planarization layer 209.

The first electrode 211 may be electrically connected with the drain electrode 208 of the thin film transistor through a contact hole provided in the planarization layer 209. Although FIG. 2 illustrates a structure in which the first electrode 211 is connected with the drain electrode 208 of the thin film transistor, the disclosure is not limited thereto, and the first electrode 211 may be connected with the source electrode 207 of the thin film transistor.

Although FIG. 2 illustrates a structure in which the first electrode 211 is a single layer, the disclosure is not limited thereto. For example, the first electrode 211 may have a multi-layer structure of two or more layers.

The first electrode 211 may include a reflective electrode.

Specifically, if the first electrode 211 has a single-layer structure, the first electrode 211 may be a reflective electrode including a reflective conductive material.

If the first electrode 211 has a multi-layer structure, at least one layer may be a reflective electrode including a reflective conductive material. The other layers than the reflective electrode may be layers formed of a transparent conductive material.

A bank 220 may be disposed on the planarization layer 209.

The bank 220 may be disposed to overlap a portion of the upper surface of the first electrode 211. The bank 220 may be disposed to expose a portion of the upper surface of the first electrode 211.

In some aspects, the bank 220 may define an emission area EA and a non-emission area NEA in the active area AA of the organic light emitting diode display 100. For example, in the active area AA, the area where the bank 220 is disposed on corresponds to the non-emission area NEA, and the area excluding the bank 220 corresponds to the emission area EA.

A light emitting layer 212 of the organic light emitting element 210 may be disposed on the first electrode 211.

The light emitting layer 212 may be disposed on the upper surface of the first electrode 211 exposed by the bank 220.

Although FIG. 2 illustrates a structure in which the light emitting layer 212 is a single layer, the disclosure is not limited thereto. The light emitting layer 212 may be formed of a multi-layered organic layer.

The light emitting layer 212 may emit light of at least one of red (R), green (G), and blue (B). However, the disclosure is not limited thereto, and the light emitting layer 212 may emit other colors of light, such as white (W).

A second electrode 213 of the organic light emitting element 210 may be disposed on the substrate 201 on which the light emitting layer 212 is disposed.

The second electrode 213 may include a transparent conductive material or a semi-transmissive material.

Although FIG. 2 illustrates a structure in which the second electrode 213 is a single layer, the disclosure is not limited thereto, and the second electrode 213 may have a multi-layer structure of two or more layers.

An encapsulation layer 230 may be disposed on the second electrode 213.

The encapsulation layer 230 may include a first encapsulation layer 231 disposed on the second electrode 213, a second encapsulation layer 232 disposed on the first encapsulation layer 231, and a third encapsulation layer 233 disposed on the second encapsulation layer 232. The first encapsulation layer 231 and the third encapsulation layer 233 may include an inorganic insulating material, and the second encapsulation layer 232 may include an organic insulating material.

The first encapsulation layer 231 and the third encapsulation layer 233 including the inorganic insulating material may serve to prevent penetration of moisture and oxygen, and the second encapsulation layer 232 including the organic insulating material may serve to delay the movement of a small amount of moisture and oxygen permeated through the third encapsulation layer 233.

Although not illustrated in the drawings, the encapsulation layer 230 may be disposed on the active area AA and the non-active area of the organic light emitting diode display 100.

The cover module 160 described in connection with FIG. 1A may be disposed on the encapsulation layer 230.

Referring to FIG. 2, the cover module 160 may be disposed in a direction that is incidental to the light emitted from the emission area EA of the display panel 110.

Each of the first adhesive layer 120, the second adhesive layer 140, and the coating layer 150 included in the cover module 160 may have high light transmittance.

Since the cover module 160 does not include a base layer that may be disposed on at least one surface of the coating layer 150, the surface hardness of the display device 100 may be increased.

In some aspects, although the cover module 160 includes the first adhesive layer 120, the polarizing plate 130, the second adhesive layer 140, and the coating layer 150 in connection with FIGS. 1A and 2, the structure of the cover module 160 according to aspects of the disclosure is not limited thereto.

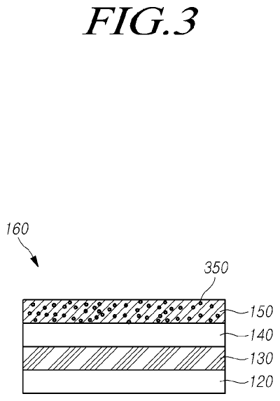

FIGS. 3, 4, 5, and 6 are views illustrating a structure of a cover module according to aspects of the disclosure.

Referring to FIG. 3, a cover module 160 may include a first adhesive layer 120, a polarizing plate 130, a second adhesive layer 140, and a coating layer 150.

The coating layer 150 may be formed of a base resin with a release agent 350 dispersed into the base resin.

Non-limiting examples of a release agent 350 include at least one of polyethylene, polypropylene, polyester, and fluorine. For example, the coating layer 150 may be formed by including the release agent 350 containing fluorine in a siloxane resin.

As illustrated in FIG. 3, the release agent 350 may be contained in the material of the coating layer 150.

Although not shown in the drawings, before the coating layer 150 is attached to the second adhesive layer 140 of the cover module 160, a protective film (not shown) may be attached to at least one surface of the coating layer 150.

Here, the protective film may protect the coating layer 150 before attaching the coating layer 150 on the second adhesive layer 140.

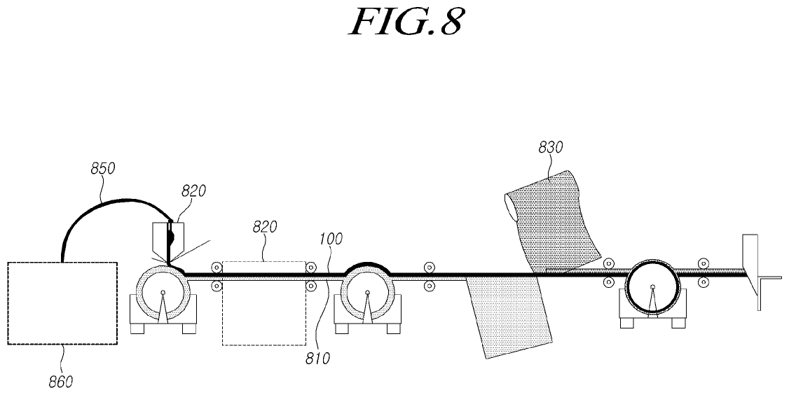

As shown in FIG. 3, as the coating layer 150 is formed on a carrier film (e.g., carrier film 810 in FIG. 8) and the coating layer 150 includes the release agent 350, after forming the coating layer 150 on the second adhesive layer 140, the carrier film may be removed without damage to the coating layer 150 when removing the protective film attached to one surface of the coating layer 150.

In some aspects, when a base layer is present between the coating layer 150 and the second adhesive layer 140, the coating layer 150 should not be separated from the base layer. Thus, a separate layer (e.g., adhesive layer) may be formed between the base layer and the coating layer 150 by adding an additive that enhances the adhesion between the base layer and the coating layer 150 or enhances the surface energy of the coating layer 150.

Further, even when a base layer is present on the coating layer 150, a separate layer may be formed between the base layer and the coating layer 150 by adding an additive that enhances the adhesion between the base layer and the coating layer 150 or enhances the surface energy of the coating layer 150.

A protective film (not shown) for protecting the coating layer 150 may be disposed on at least one surface of the coating layer 150 included in the cover module 160 according to aspects of the disclosure. The protective film should be separated from the surface of the coating layer 150, the material of the coating layer having at least one surface where the base layer is disposed may be different from the material included in the coating layer 150 according to aspects of the disclosure.

In some aspects, the coating layer 150 includes at least one release agent 350. to improve from components other than the second adhesive layer 140 without damaging the surface of the coating layer 150. Non-limiting examples of a release agent 350 include polyethylene, polypropylene, polyester, and fluorine.

Although FIG. 3 illustrates a structure in which the release agent 350 is included in the coating layer 150, the structure of the cover module 160 according to aspects of the disclosure is not limited thereto.

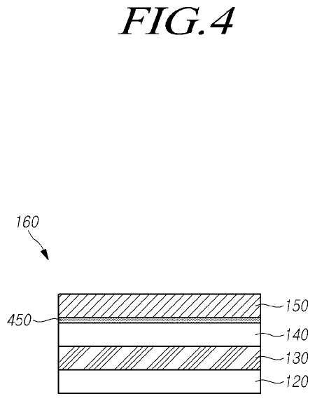

For example, as shown in FIG. 4, a release agent material layer 450 may be coated on a surface of the coating layer 150.

Accordingly, referring to FIG. 4, the release agent material layer 450 may be disposed between the coating layer 150 and the second adhesive layer 140.

The thickness of the release agent material layer 450 may be smaller than the thickness of the coating layer 150 and the thickness of the second adhesive layer 140.

Further, although FIG. 4 illustrates a structure in which the release agent material layer 450 is coated on the entire rear surface of the coating layer 150, the structure of the cover module 160 according to aspects of the disclosure is not limited thereto.

For example, the release agent material layer 450 may be coated on the entire front surface of the coating layer 150, and in some cases, the release agent material layer 450 may be coated on each of the front and rear surfaces of the coating layer 150.

Although not shown in the drawings, the release agent material layer 450 that is disposed on at least one surface of the coating layer 150 may have a pattern. For example, the release agent material layer 450 may be positioned on the rear surface of the coating layer 150 and may have a hole formed to expose a portion of the rear surface of the coating layer 150.

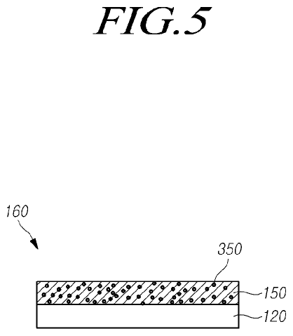

Referring to FIG. 5, the cover module 160 according to aspects of the disclosure may include a first adhesive layer 120 and a coating layer 150.

The cover module 160 of FIG. 5 may be disposed on the display panel 110.

Accordingly, the first adhesive layer 120 may be disposed on the display panel 110, and the coating layer 150 may be disposed on the first adhesive layer 120.

As illustrated in FIG. 5, the cover module 160 may not include the polarizing plate 130 and the second adhesive layer 140, which is different from the cover module 160 illustrated in FIG. 3.

The coating layer 150 may be adhered to the upper surface of the first adhesive layer 120.

In this case, it is possible to suppress reflection of external light through a plurality of black matrices and a plurality of color filters in the display panel 110. Specifically, external light reflection may be prevented because the plurality of black matrices and the plurality of color filters disposed in the display panel 110 absorb external light, which increases visibility.

The first adhesive layer 120 of the cover module 160 of FIG. 5 may attach the coating layer 150 to the display panel 110.

Since the cover module 160 of FIG. 5 includes only the first adhesive layer 120 and the coating layer 150, the thickness may be reduced and transmittance may be enhanced. Further, bending, folding, sliding, and rolling may be improved based on the reduced thickness of the cover module 160 of FIG. 5.

Referring to FIG. 5, a release agent 350 may be included in the coating layer 150, but the structure of the cover module 160 according to aspects of the disclosure is not limited thereto.

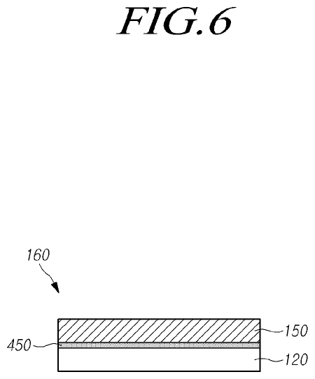

Referring to FIG. 6, the cover module 160 may include a release agent material layer 450 that is disposed between the first adhesive layer 120 and the coating layer 150.

The thickness of the release agent material layer 450 may be smaller than the thickness of the first adhesive layer 120 and the thickness of the coating layer 150.

In some aspects, a protective film (not shown) may be attached to one surface of the release agent material layer 450 before attaching the release agent material layer 450 and the coating layer 150 on the first adhesive layer 120.

The protective film attached to the release agent material layer 450 may serve to support the coating layer 150 while protecting the surface of the coating layer 150.

The protective film may be disposed on the other surface of the release agent material layer 450 where the coating layer 150 is not disposed.

The protective film may be removed while attaching the coating layer 150 and the release agent material layer 450 on the first adhesive layer 120.

The release agent material layer 450 may comprise a material that may be easily separated from the protective film. Non-limiting examples of a material that may be easily separated from the protective film include at least one of polyethylene, polypropylene, polyester, and fluorine.

As shown in FIGS. 5 and 6, as the release agent 350 is included in the coating layer 150 or the release agent material layer 450 is disposed on at least one surface of the coating layer 150, it is possible to provide a coating layer 150 that does not require a separate base layer.

When the cover module 160 according to aspects of the disclosure is disposed on the display panel 110, since the coating layer 150 is attached to an outer surface of the display device 100, the surface hardness of the display device 100 may be substantially the same as the surface hardness of the coating layer 150. In this case, parameters that are substantially equal are within a narrow range and have the same effect. For example, a surface hardness of 8H is substantially equal to a surface hardness of 9H.

Further, since a separate film or base layer for protecting or supporting the coating layer 150 is not required, the thickness of the cover module 160 may be reduced, and bending, folding, sliding, rolling, or other types of transformation may be improved.

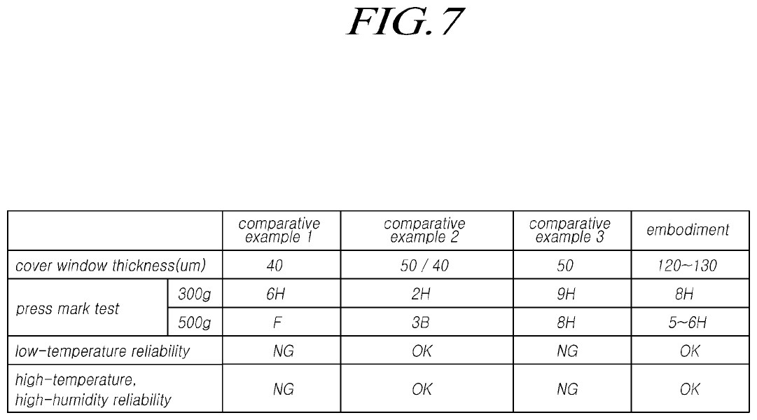

The features are discussed below with reference to FIG. 7.

FIG. 7 is a view comparing the characteristics of cover modules according to aspects of the disclosure.

In FIG. 7, the cover module referred to as comparative example 1 includes a cover window disposed on the display panel, and the cover window includes a coating layer and a base layer supporting the coating layer. The base layer of comparative example 1 is formed of colorless polyimide.

The cover module referred to as comparative example 2 in FIG. 7 includes a cover window, and the cover window includes a coating layer, a base layer disposed on the coating layer, and another coating layer disposed on the base layer. The base layer of comparative example 2 is be formed of polyester.

In FIG. 7, the cover module referred to as comparative example 3 may include a cover window, and the cover window may be formed of glass.

The cover module 160 identified in FIG. 7 and compared to the comparative examples 1-3 may correspond to the cover module 160 shown in FIG. 3.

An anti-fingerprint coating may be applied to the cover window of comparative examples 1 to 3 and the top surface of the coating layer according to the embodiment.

The thicknesses of the coating layers according to comparative examples 1 and 2 is 40 μm, and the thickness of the coating layer according to comparative example 3 is 50 μm.

The thickness of the coating layer 150 according to the cover module 160 is 120 μm to 130 μm.

The pencil hardness of the cover windows of comparative examples 1 to 3 and the coating layer of the cover module 160 was measured through a press mark test using 300 g and 500 g weights.

The pencil hardness decreases in the following order: 9H, 8H, 7H, 6H, 5H, 4H, 3H, 2H, F, HB, B, 2B, 3B, 4B, 5B, 6B, 7B, 8B and 9B.

Referring to FIG. 7, the pencil hardness of the cover window according to comparative example I measured with the 300 g weight was 6H, and the pencil hardness of the cover window according to comparative example I measured with the 500 g weight was F.

Further, the pencil hardness of the cover window according to comparative example 2 measured with the 300 g weight was 2H, and the pencil hardness of the cover window according to comparative example 2 measured with the 500 g weight was 3B.

The pencil hardness of the cover window according to comparative example 3 measured with the 300 g weight was 9H, and the pencil hardness of the cover window according to comparative example 3 measured with the 500 g weight was 8H.

Referring to FIG. 7, the pencil hardness of the coating layer of the cover module 160 measured with the 300 g weight was 8H, and the pencil hardness of the coating layer of the cover module 160 measured with the 500 g weight was 6H.

As such, FIG. 7 illustrates that the pencil hardness of the cover module 160 is greater than the pencil hardness of the cover modules of comparative example 1 and comparative example 2. Further the pencil hardness of the cover module 160 is similar to the pencil hardness of the cover module according to comparative example 3. In other words, the surface hardness of the cover module 160 is substantially equal to the surface hardness of glass.

Referring to FIG. 7, the low-temperature reliability and high-temperature reliability of the cover modules according to comparative examples 1 to 3 and the cover module 160 may be compared.

The low-temperature reliability test realized a curvature of 1.5 R under the conditions of a temperature of 0° C. and 0.5 Hz.

The high-temperature reliability test realized a curvature of 1.5 R under the conditions of a temperature of 60° ° C., a humidity of 90%, and 0.5 Hz.

Referring to FIG. 7, it may be identified that the cover module according to comparative example 1 and the cover module according to comparative example 3 have poor reliability in low temperature, high temperature and high humidity environments.

In other words, the cover module 160 has high surface hardness and high reliability of being undamaged even when curvature is applied in a high temperature and high humidity environment.

It has been described that the coating layer 150 may be disposed on the display panel 110 without a separate base layer.

A process for forming the coating layer is briefly described below.

FIG. 8 is a view schematically illustrating a process of forming a coating layer of a cover module according to aspects of the disclosure.

Referring to FIG. 8, the coating layer material 850 may be formed on the carrier film 810 by a pump 860.

The coating layer material 850 may include a siloxane resin. Further, the coating layer material may include a release agent, such as fluorine, but aspects of the disclosure are not limited thereto.

A coating layer material 850 formed on a carrier film 810 may be cured through heat treatment and drying in an oven 820, forming a coating layer.

A protective film 830 may be disposed on the coating layer.

The carrier film 810 disposed on the rear surface of the coating layer may be removed.

Since the coating layer includes the release agent material, the coating layer may not be damaged when removing the carrier film 810.

A protective film may be additionally disposed on the rear surface of the coating layer from which the carrier film 810 has been removed, but aspects of the disclosure are not limited thereto, and no protective film may be disposed on the rear surface of the coating layer from which the carrier film 810 has been removed.

Thereafter, punching may be performed when the protective film 830 is disposed on at least one surface of the coating layer.

The coating layer may be disposed on the adhesive layer as shown in FIGS. 1A and 3 to 6, and when applied to a display device, the protective film 830 disposed on the coating layer may be removed.

A brief description of the cover module and the display device according to aspects of the disclosure described above is as follows.

Aspects of the disclosure may provide a display device 100 including a display panel and a cover module 160 disposed on the display panel. The cover module 160 may include an adhesive layer (e.g., first adhesive layer 120 or second adhesive layer 140) disposed on the display panel 110 and a coating layer 150 is disposed on the adhesive layer 120 or 140. The coating layer 150 may be disposed on an outer surface of the display device 100. A surface of the coating layer 150 contacts the adhesive layer 120 or 140. A surface hardness of the display device 100 may be substantially identical to a hardness of the coating layer 150. The coating layer 150 may include a base resin and a release agent 350.

The base resin of the coating layer 150 may include a siloxane resin, and the release agent 350 may include fluorine.

The cover module 160 may include a first adhesive layer 120 disposed on the display panel 110, a polarizing plate 130 disposed on the first adhesive layer 120, a second adhesive layer 140 disposed on the polarizing plate 130, and a coating layer 150 disposed on the second adhesive layer 140.

The cover module 160 may include a first adhesive layer 120 disposed on the display panel 110 and a coating layer 150 disposed on the first adhesive layer 120.

The cover module 160 may include a first adhesive layer 120 disposed on the display panel 110, a polarizing plate 130 disposed on the first adhesive layer 120, a second adhesive layer 140 disposed on the polarizing plate 130, a release agent material layer 450 disposed on the second adhesive layer 140, and a coating layer 150 disposed on the release agent material layer 450.

The release agent material layer 450 may include fluorine.

The pencil hardness of the coating layer 150 may be equal to or less than a pencil hardness of glass and greater than a pencil hardness of polyimide and polyester.

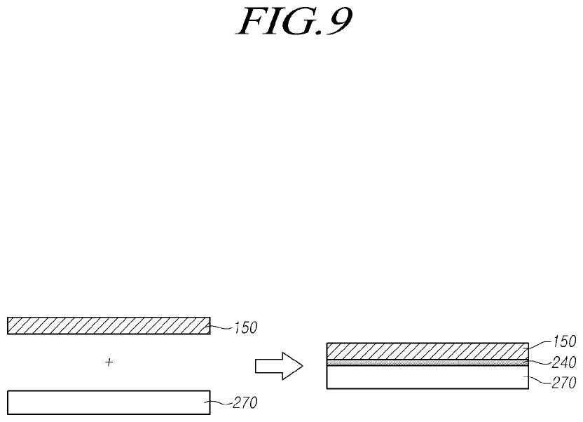

FIG. 9 is a view schematically illustrating a process of bonding a coating layer to a rigidity reinforcement layer according to aspects of the disclosure.

Referring to FIG. 9, an adhesive layer 240 may be disposed between the rigidity reinforcement layer 270 and the coating layer 150, and the rigidity reinforcement layer 270 and the coating layer 150 may be bonded through the adhesive layer 240.

The display device 100 of the disclosure may be capable of folding, bending, sliding, and rolling.

According to aspects of the disclosure, a cover module is provided having excellent flexibility and high surface hardness by omitting a base layer. A display device including the cover module, and a method of forming the cover module is also provided.

According to aspects of the disclosure, a cover module by including a coating layer containing a release agent, the cover modules may be high reliability even when bent, folded, slid, and rolled.

The above description has been presented to enable any person skilled in the art to make and use the technical idea of the disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the disclosure. The above description and the accompanying drawings provide an example of the technical idea of the disclosure for illustrative purposes only. That is, the disclosed aspects are intended to illustrate the scope of the technical idea of the disclosure.

What is claimed:

1. A display device, comprising:
a display panel; and
a cover module disposed on the display panel,
wherein the cover module includes an adhesive layer disposed on the display panel and a coating layer,
wherein the coating layer is disposed on an outermost surface of the display device, and
wherein a surface hardness of the display device is substantially identical to a surface hardness of the coating layer.

2. The display device of claim 1, further comprising a release agent layer, wherein the release agent layer includes at least one of polyethylene, polypropylene, polyester, or fluorine.

3. The display device of claim 1, wherein the coating layer includes at least one of acrylate siloxane or epoxy siloxane.

4. The display device of claim 1, wherein the cover module includes:
a polarizing plate disposed on the adhesive layer; and
a second adhesive layer disposed on the polarizing plate,
wherein the coating layer is disposed on the second adhesive layer.

5. The display device of claim 1, wherein the cover module includes:
a polarizing plate disposed on the adhesive layer;
a second adhesive layer disposed on the polarizing plate; and
a release agent material layer disposed on the second adhesive layer,
wherein the coating layer is disposed on the second adhesive layer.

6. The display device of claim 5, wherein the release agent material layer includes at least one of polyethylene, polypropylene, polyester, and fluorine.

7. The display device of claim 5, wherein a thickness of the release agent material layer is less than a thickness of the coating layer and a thickness of the second adhesive layer.

8. The display device of claim 1, wherein a pencil hardness of the coating layer is less than or substantially equal to a pencil hardness of glass and greater than a pencil hardness of polyimide and polyester.

9. The display device of claim 1, wherein the coating layer comprises a thickness of 50 μm to 300 μm.

10. The display device of claim 1, wherein the coating layer comprises a modulus of 200Mpa to 2000Mpa.

11. The display device of claim 1, wherein the adhesive layer comprises a thickness of 5 μm to 50 μm.

12. The display device of claim 1, wherein the adhesive layer comprises a modulus of 0.01Mpa to 1Mpa.

13. The display device of claim 1, wherein the display device is capable of folding, bending, sliding, and rolling, and
wherein the display device comprises a bending radius of 1.5R to 7.0R.

14. The display device of claim 1, wherein the cover module further includes a rigidity reinforcement layer disposed under the adhesive layer configured to provide a surface rigidity to the cover module.

15. The display device of claim 14, wherein the rigidity reinforcement layer includes chemically tempered glass.

16. The display device of claim 15, wherein the rigidity reinforcement layer comprises a thickness of 70 μm to 90 μm, and
wherein the rigidity reinforcement layer comprises a chemical reinforcement depth of 12 μm to 16 μm.

17. The display device of claim 15, wherein a thickness of the adhesive layer is less than a thickness of the rigidity reinforcement layer and a thickness of the coating layer, and
wherein the adhesive layer comprises a thickness of 5 μm to 15 μm.

18. A cover module, comprising:
an adhesive layer; and
a coating layer,
wherein the coating layer is disposed on an outermost surface of the cover module, and
wherein a surface hardness of the cover module is substantially identical to a surface hardness of the coating layer.

19. A method of forming a cover module, comprising:
forming a coating layer material based on a base resin:
applying the coating layer material to a carrier film and curing the coating layer material to form a coating layer, wherein a release agent is configured to release the carrier film and comprises includes at least one of polyethylene, polypropylene, polyester, or fluorine;
applying a removable protective film to an exposed surface of the coating layer; and
removing the carrier film to form the cover module,
wherein the exposed surface from removing the carrier film is applied to a flexible display panel and configures the display panel to have a surface hardness of the coating layer.

20. The method of claim 19, wherein the cover module omits a base layer comprising at least one of a transparent polyimide, polyester, acrylic, and urethane.

21. The method of claim 19, wherein the cover module only includes an adhesive layer and the coating layer material.

22. The method of claim 19, wherein forming the coating layer material comprises mixing the release agent with the base resin.

23. The method of claim 19, wherein a release agent layer including the release agent is formed on the carrier film.
